(19) United States
(12) Patent Application Publication
(10) Pub. No.: US 2010/0184268 A1
(43) Pub. Date: Jul. 22, 2010

(54) METHOD FOR PRODUCING A SEMICONDUCTOR DEVICE HAVING A PORTION IN WHICH A GROOVE IS EMBEDDED WITH AN OXIDE FILM

(75) Inventor: Toshiyuki HIROTA, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/749,988

(22) Filed: Mar. 30, 2010

Related U.S. Application Data
(62) Division of application No. 12/135,412, filed on Jun. 9, 2008.

(30) Foreign Application Priority Data
Jun. 7, 2007 (JP) 2007-151767

(51) Int. Cl. H01L 21/762; H01L 21/3105

(52) U.S. Cl. 438/400; 438/781; 257/E21.547; 257/E21.242

(57) ABSTRACT

A coating composition for forming an oxide film, which can suppress the phenomenon of an increased wet etching rate caused by a part of the SOG film embedded inside a groove becoming low-density, and which can suppress the volume expansion coefficient to a low level, and a method for producing a semiconductor device using the same are provided. An oxide film is formed inside a groove by: coating a coating composition for forming an oxide film, which contains a polysilazane or a hydrogenated silsesquioxane, and a polysilane, on a substrate having a groove; and thereafter heat treatment in an oxidizing atmosphere. This method is suitable for forming a device isolation region and a wiring interlayer dielectric film.

### BACKGROUND OF THE INVENTION

1. Field of the Invention

An exemplary aspect of the invention relates to a coating composition for forming an oxide film which constitutes a semiconductor substrate device isolation region or a wiring interlayer dielectric film, and a method for producing a semiconductor device using the same.

2. Description of the Related Art

Related art for forming a device isolation region (STI: Shallow Trench Isolation), in which a trench formed among the device forming regions of a semiconductor substrate is embedded with an insulator, will now be described with reference to FIG. 3.

First, on a semiconductor substrate 301, a pad oxide film 302 (thickness: 9 nm) is formed by thermal oxidation and a nitride film 303 (thickness: 120 nm) is formed by LP-CVD. A photoresist 304 pattern is formed on the nitride film 303 using a known lithography technique (FIG. 3(a)).

Next, with the photoresist 304 as a mask, the nitride film 303 and the pad oxide film 302 are patterned using a known etching technique. Then, the photoresist 304 is removed by ashing or the like in an oxygen plasma atmosphere. Next, with the patterned nitride film 303 as a mask, the semiconductor substrate 301 is etched to form a trench 306 (depth: about 180 nm) for device isolation. At this stage, the nitride film 303 is etched so that the thickness decreases from the original 120 nm to 80 nm. Further, to remove the layers damaged by the etching, a thermal oxide film 305 having a thickness of about 10 nm is formed on the inner walls of the trench (FIG. 3(b)).

Next, a CVD oxide film 308 is deposited by high-density plasma CVD (HBP-CVD) (FIG. 3(c)).

Then, the nitride film 303 is ground as far as its upper edge as a stopper by CMP using a ceria slurry to planarize the surface (FIG. 3(d)).

Further, the upper edge of the CVD oxide film 308 is lowered as far as the vicinity of the lower edge of the nitride film 303 by etching with hydrofluoric acid. At this stage, the upper edge of the CVD oxide film 308 is set so as to come to about 20 to 40 nm above the upper edge of the semiconductor substrate 301 (FIG. 3(e)). Although it is ultimately desirable to align the upper edge of the CVD oxide film 308 and the upper edge of the semiconductor substrate 301, a portion is left at this stage so that the CVD oxide film 308 can be etched when the pad oxide film 302 is removed and the gate oxide film 309 is reset in a subsequent step.

Next, the nitride film 303 is selectively removed by etching with hot phosphoric acid. Then, after conducting a necessary impurity ion implantation step, the pad oxide film 302 is removed with hydrofluoric acid. After washing, a gate oxide film 309 is formed by thermal oxidation (FIG. 3(f)).

According to the above-mentioned method, the upper face of the device forming region of the semiconductor substrate 301 can be aligned with the upper face of the device isolation region. After the gate oxide film 309 is formed, a gate electrode is formed thereon. Patterning and the necessary impurity ion implantation are then carried out to form a transistor (not shown).

However, with the miniaturization of devices, trench widths are now heading towards dimensions below 60 nm. As a result, the limits for trench embedding by HDP-CVD are starting to be seen, with a void 410 sometimes now being formed in the trench (FIG. 4(a)). The void 410 is exposed to the surface in subsequent steps, whereby an unintended hollow 411 is formed in the device isolation region (FIG. 4b)). If this hollow 411 is formed, short-circuiting occurs between the adjacent gates in the subsequent steps, thereby decreasing the yield. The formation of the void 410 cannot be completely suppressed even if care is taken with the HDP-CVD deposition conditions, or the deposition is carried out over multiple steps (repeating deposition and etching). Further, there has been no success in terms of improving the deposition apparatus hardware.

Accordingly, as a new STI formation method, SOG (Spin-on-Glass) films are attracting attention. For example, there have been disclosed techniques in which a hydrogenated silsesquioxane (HSQ) and a polysilane (polyperhydrosilazane) are coated as a coating composition for an SOG film, and then the coated composition is heat treated in an oxidizing atmosphere (Japanese Patent Application Laid-Open Nos. 2002-367980, 2005-347636 and 2007-027697). Recently the use of a polysilazane is particularly promising.

It is noted that an STI formation method carried out by embedding a trench with an SOG film is basically the same as the method described using FIG. 3, except for embedding the SOG film. However, to prevent the semiconductor substrate 301 from oxidizing during the oxidation treatment of the SOG film 508 embedded in the groove, a nitride film 507 having a thickness of 5 nm, which has an oxidation resistance and acts as an oxidizing species diffusion barrier, is formed over the whole surface of the thermal oxide film 305 by LP-CVD, before the SOG film 508 is coated (FIG. 5(a)). The coating composition for the SOG film exhibits very good groove initial embedding properties, so that a void such as that in FIG. 4(a) is not formed.

However, it has been found that if a polysilazane, for example, is coated and then subjected to a heat treatment in an oxidizing atmosphere to form the oxide film, a low-density region 511 in a part of the film embedded inside the trench is formed (FIG. 5(b)). In this low-density region 511, the quality of the film deteriorates and the wet etching rate is several times higher than that in the other regions. Therefore, the low-density region 511 is selectively etched by the CMP and by wet etching which are carried out to align the upper edge of the device isolation region with the upper edge of the semiconductor substrate 501 of the device forming region. As a result, the intended shape cannot be formed (FIG. 5(c)).

This problem does not only occur during STI formation, but is also commonly observed when a groove having a large aspect ratio is embedded with an SOG film and then subjected to a heat treatment of at least a certain temperature (about 600° C.).

For example, for the formation of a wiring interlayer dielectric film between DRAM gate electrodes (word lines), there is a demand for a lower temperature process (not more than 700° C.) and thus, for a device having a wiring interlayer interval at the 60 nm level, the BPSG (Boron Phosphorus Silicon Glass) used in related art cannot sufficiently reflow, whereby void formation becomes a problem like when forming an STI. Accordingly, the use of a SOG film has been tried in place of BPSG. However, like when forming the STI, a part of the SOG film embedded inside the groove becomes low-density, so that the wet etching rate increases. Thus, during the wet treatment by hydrofluoric acid and the like when forming a contact plug, the contact hole widens, which becomes a cause for short-circuiting between adjacent contact plugs.

On the other hand, there have also been disclosed techniques using a polysilane for the coating composition for an SOG film (Japanese Patent Application Laid-Open Nos. 2003-55556, 2003-115532 and 2003-133306).

To resolve the above-mentioned problem that the quality of an SOG film embedded in an STI or inter-wiring groove deteriorates, inventors of an exemplary embodiment investigated the mechanism by which the film quality deteriorates.

First, when a polysilazane was spin coated onto a flat silicon substrate as a coating composition for an SOG film and the coated polysilazane was heat treated in an oxidizing atmosphere, the thickness of the film was reduced from 450 nm to 350 nm, and a volume contraction of about 23% was observed. Further, the phenomenon of an increased wet etching rate for the contracted SOG film was not found.

Further, when the crystal distortion of the silicon substrate crystals in the vicinity of the polysilazane SOG film embedded in an STI trench portion was measured by NBD (nano-beam diffraction), it was indicated that the SOG film had a strong tensile stress. On the other hand, from the measured results of FT-IR, the polysilazane SOG film embedded in the STI trench portion was almost completely SiO₂, which makes it difficult to believe that any unreacted polysilazane remained.

From the above results, while the SOG film embedded inside a narrow groove tried to contract from the heat treatment, the film could not contract as it was enclosed by the surrounding walls. It is considered that the stress remained in the film, thus making the film low-density, whereby the wet etching rate increased.

Consequently, inventors of an exemplary embodiment investigated a method of alleviating the stress by compensating in some kind of manner for the volume contracting so that the SOG film itself could contract. Specifically, inventors of an exemplary embodiment tried to omit the nitride film 507, which is provided to prevent the semiconductor substrate 301 from oxidizing during the oxidation heat treatment of the SOG film 508, and utilized the volume expansion when the semiconductor substrate 301 is oxidized (volume expands by a factor of about 2 when going from Si to SiO₂). As a result, it became clear that although they could suppress the phenomenon of a very high SOG film wet etching rate, the thermal oxide film 305 became thicker, thereby causing the semiconductor substrate device forming region to become narrower, and thus this method was not practical (FIG. 6).

It was also investigated to provide the nitride film 507, then to form a silicon film 712 above the nitride film 507 by CVD, and to utilize the volume expansion caused by oxidation of the silicon film 712 (FIG. 7). With this method, although some effects were exhibited for grooves of a certain size, for relatively wide grooves the phenomenon of an increased wet etching rate could not be suppressed. Further, it became clear that, depending on the groove, the way that stress is applied is different, which can cause unexpected effects on transistor properties such as threshold voltage and ON current.

Further, inventors of an exemplary embodiment tried the methods using a polysilane described in Japanese Patent Application Laid-Open Nos. 2003-55556, 2003-115532 and 2003-133306. As a result, although the phenomenon of an increased wet etching rate for the part of the SOG film embedded inside the groove could be suppressed, the formed SOG film had a large volume expansion coefficient, and the substrate curved in a convex manner, and thereby, there was a problem that delivery errors in the semiconductor manufacturing apparatus occurred. Further, silicon crystals formed after the polysilane was heat treated and these crystals could not all be oxidized as is, which became a factor in problems such as an increased localized leak current.

### SUMMARY OF THE INVENTION

An exemplary object of the invention is to provide a coating composition for forming an oxide film, which can suppress the phenomenon of an increased wet etching rate caused by a part of the SOG film embedded inside a groove becoming low-density, and which can suppress the volume expansion coefficient to a low level, and a method for producing a semiconductor device using the same.

An exemplary aspect of the invention is a coating composition for forming an oxide film comprising: a polysilazane or a hydrogenated silsesquioxane; and a polysilane.

Further, an exemplary aspect of the invention is a method for producing a semiconductor device having a portion in which a groove is embedded with an oxide film, comprising: coating the above-mentioned coating composition for forming an oxide film on a substrate having the groove; and forming the oxide film inside the groove by heat treatment in an oxidizing atmosphere.

According to an exemplary aspect of the invention, a coating composition for forming an oxide film, which can suppress the phenomenon of an increased wet etching rate caused by a part of the SOG film embedded inside a groove becoming low-density, and which can suppress the volume expansion coefficient to a low level, and a method for producing a semiconductor device using the same can be provided.

### BRIEF DESCRIPTION OF THE DRAWINGS

FIG. 1 is a schematic cross-sectional view illustrating the state of each step in forming a device isolation region having an oxide film embedded in a semiconductor substrate according to an exemplary embodiment;

FIG. 2 is a schematic cross-sectional view illustrating the state of each step in forming a gate interlayer dielectric film having an oxide film embedded on a semiconductor substrate according to an exemplary embodiment;

FIG. 3 is a schematic cross-sectional view illustrating the state of each step in forming a device isolation region having an oxide film embedded in a semiconductor substrate according to a related art;

FIG. 4 is a schematic cross-sectional view for describing the problems which occur in conjunction with miniaturizing a device;

FIG. 5 is a schematic cross-sectional view for describing the problems which occur when embedding a trench with an SOG film;

FIG. 6 is a schematic cross-sectional view illustrating the state where a trench is embedded with an SOG film without having formed a nitride film; and

FIG. 7 is a schematic cross-sectional view illustrating the state where a trench is embedded with an SOG film after first having formed a silicon film on a nitride film.

### DETAILED DESCRIPTION OF EXEMPLARY EMBODIMENT

### Coating Composition for Forming an Oxide Film

A coating composition for forming an oxide film of an exemplary embodiment contains a polysilazane or a hydrogenated silsesquioxane, and a polysilane. During production of a semiconductor device having a portion (a device isolation region, a wiring interlayer dielectric film etc.) in which a groove is embedded with an oxide film, the coating composition for forming an oxide film of an exemplary embodiment can be preferably used for forming that oxide film.

The polysilazane (polyperhydrosilazane) is a compound represented by (SiH₂NH)ₙ (n being a positive integer), and has a structure represented by the following formula (A). The polysilazane is commercially available as, for example, a product manufactured by AZ Electronic Materials under the trade name “Spinfil 45002” (a mixture of 21 wt % of a polysilazane and 79 wt % of dibutyl ether).

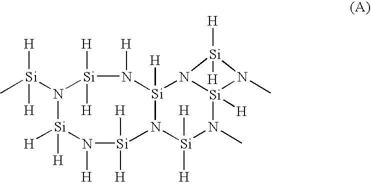

The hydrogenated silsesquioxane is a compound represented by (SiHO_{3/2})ₙ (n being a positive integer), and has a structure represented by the following formula (B). The hydrogenated silsesquioxane is commercially available as, for example, a product manufactured by Tokyo Ohka Kogyo Co., Ltd., under the trade name “Type-12”.

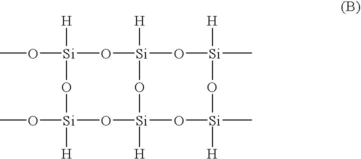

Either the polysilazane or the hydrogenated silsesquioxane may be used alone, or both of these may be used together.

As the polysilane, any of a linear polysilane, a cyclic polysilane or a cage-shaped polysilane may be used. The polysilane may be used as a single kind, or as many kinds in combination. Considering the thermal stability and storability of the prepared coating composition for forming an oxide film, it is preferable to use the cyclic polysilane as the polysilane.

The linear polysilane is a compound having a structure represented by the following formula (C). Among them, it is preferable to use a linear polysilane represented by the following formula (1).

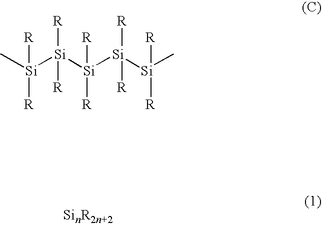

In the formula (1), n denotes an integer of 3 or higher, and each R independently represents hydrogen atom, a halogen atom, a silsesquioxane residue or a polysilazane residue. Preferably, n is from 5 to 100.

The cyclic polysilane is a compound having a structure represented by the following formula (D). Among them, it is preferable to use a cyclic polysilane represented by the following formula (2).

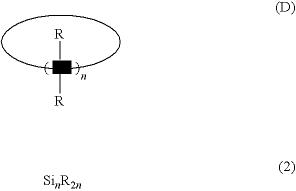

In the formula (2), n denotes an integer of 3 or higher, and each R independently represents hydrogen atom, a halogen atom, a silsesquioxane residue or a polysilazane residue. Preferably, n is from 3 to 6.

Specific examples of the cyclic polysilanes include cyclopentasilane represented by the following formula (2a), cyclohexasilane represented by the following formula (2b), and silylcyclopentasilane represented by the following formula (2c).

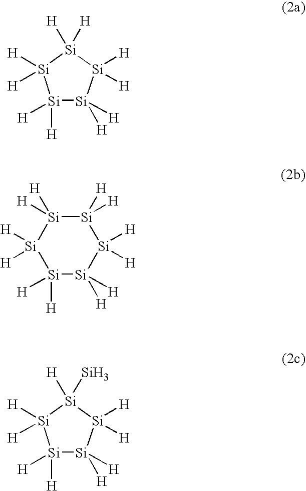

Since the preferred composition ratio of the polysilazane or the hydrogenated silsesquioxane to the polysilane depends on the polymerization degree of each of these polymers, the composition ratio may be appropriately adjusted according to the purpose. For example, the volume change from after baking (driving off the solvent) at 300 to 400° C. to after a thermal oxidation treatment at 500 to 700° C. is preferably adjusted to from −3% to +7%. If the volume change is smaller than −3%, the wet etching rate of the formed film is higher than that for a film formed by HDP-CVD, and the suppression of crystal defects tends to be insufficient. On the other hand, if the volume change is larger than +7%, a tendency for the unevenness in the threshold voltage of the transistor to increase can be seen.

More specifically, based on total of 100 parts by weight of the polysilazane or the hydrogenated silsesquioxane and the polysilane, the polysilane is preferably 10 to 50 parts by weight. By having 10 parts by weight or more of the polysilane, the phenomenon of an increased wet etching rate can be effectively suppressed. By having 50 parts by weight or less of the polysilane, transfer errors in the semiconductor manufacturing apparatus and the increase in localized leak current can be effectively suppressed. More preferably, the polysilane is 20 to 40 parts by weight.

A coating composition for forming an oxide film of an exemplary embodiment may be free from solvent, or may be a solution in which the above-mentioned components are dissolved in a solvent. The solvent is not especially limited, so long as it does not react with the above-mentioned components. Examples of the solvents include hydrocarbon solvents such as n-pentane, n-hexane, n-heptane, n-octane, decane, dicyclopentane, benzene, toluene, xylene, tetrahydronaphthalene and decahydronaphthalene; ether solvents such as diethyl ether, dipropyl ether, dibutyl ether, ethylene glycol dimethyl ether, ethylene glycol diethyl ether, ethylene glycol methylethyl ether, diethylene glycol dimethyl ether, diethylene glycol diethyl ether, diethylene glycol methylethyl ether, tetrahydrofuran, tetrahydropyran, 1,2-dimethoxyethane, bis(2-methoxyethyl)ether and p-dioxane; and polar solvents such as propylene carbonate, y-butyrolactone, N-methyl-2-pyrrolidone, dimethyl formamide, acetonitrile, dimethyl sulfoxide, methylene chloride and chloroform. Among them, hydrocarbon solvents are preferable from the viewpoint of the stability of the solution. The solvent can be used alone or in admixture of two kinds or more. When using the solvent, the concentration of the solvent is preferably set such that the total of the polysilazane or the hydrogenated silsesquioxane and the polysilane is 20 to 30 wt %.

For example, since cyclopentasilane, which is one kind of cyclic polysilanes, is a liquid at ordinary temperatures, and can dissolve a polysilazane, a mixture of a polysilazane and cyclopentasilane can be used as a coating composition for forming an oxide film as is. Further, to adjust the viscosity of this coating composition for forming an oxide film, another organic solvent may also be used.

Further, if a cyclic polysilane such as cyclopentasilane is irradiated with UV light, part of the ring opens, thereby forming a linear polysilane which can be polymerized with another cyclopentasilane or a polysilazane. In such a case, the coating composition for forming an oxide film will contain both a cyclic polysilane and a linear polysilane.

### <Method for Producing Semiconductor Device>

A method for producing a semiconductor device of an exemplary embodiment is a method for producing a semiconductor device having a portion in which a groove is embedded with an oxide film, and comprises coating the above-mentioned coating composition for forming an oxide film on a substrate having the groove, and forming the oxide film inside the groove by heat treatment in an oxidizing atmosphere.

As the method for coating the coating composition for forming an oxide film on a substrate having a groove, spin coating is preferable.

While the heat treatment may be carried out as is after forming the coating film by coating the coating composition for forming an oxide film, it is preferable to irradiate a light such as UV light on the coating composition for forming an oxide film. The polymerization degree of the coating composition for forming an oxide film can be increased as a result of this light irradiation. The light irradiation may be carried out on the coating composition for forming an oxide film not only after coating but also before coating, and both before and after coating. The wavelength of the irradiated light can be selected from 170 to 600 nm, for example.

It is preferred to volatilize an unreacted polysilane and a solvent by baking after the coating (in the case of irradiating with a light, after the light irradiation). The baking can be carried out in an inert atmosphere or air at 300° C., for example.

Since a polysilane is easily oxidized in air, it is preferred to carry out each of the coating, the light irradiation and the baking step in an inert atmosphere such as nitrogen.

The coated film formed by coating the coating composition for forming an oxide film is heat treated in an oxidizing atmosphere. Examples of the oxidizing atmospheres include water vapor, oxygen, ozone and the like.

While this heat treatment may be carried out at a single temperature stage selected from 300 to 800° C., for example, it is preferred to carry out at two temperature stages. If carrying out the heat treatment at two temperature stages, the temperature for the first heat treatment at the former stage is set lower than the temperature for the second heat treatment at the latter stage. For example, it is preferred to carry out the first heat treatment at 300 to 450° C. in a water vapor atmosphere, and then carry out the second heat treatment at 500 to 700° C. in a water vapor atmosphere. The heat treatment time is preferably 10 to 30 minutes for each stage.

The reason why the two-stage heat treatment is carried out in this way at a relatively low temperature and a relatively high temperature is as follows. First, by heat treatment at a relatively low temperature of 300 to 450° C., at which marked film contraction does not occur, contraction of the film is suppressed while the SiO₂ skeleton in the SOG film is formed. As a result, stress is captured inside the SOG film, avoiding as much as possible stress from being applied on the semiconductor substrate. Then, by heat treatment at a relatively high temperature of 500 to 700° C., an unreacted polysilane oxidizes and turns into silicon dioxide, whereby the stress inside the SOG film can be alleviated.

Subsequently, it is preferred to anneal at 800 to 1,000° C. in an inert atmosphere such as nitrogen so that the SOG film is densified. Here, the annealing in an inert atmosphere is carried out to prevent the semiconductor substrate from oxidizing as a result of the oxidation resistance of the nitride film for preventing oxidation being degraded.

A method as mentioned above for producing a semiconductor device of an exemplary embodiment is suitable as a method for forming a device isolation region (STI) by embedding a trench formed among the device forming regions of a semiconductor substrate with an oxide film.

Further, a method for producing a semiconductor device of an exemplary embodiment is effective for a method in which a groove is embedded with an SOG film and a thermal load of 450° C. or more to 700° C. or less is applied. A wiring interlayer dielectric film, such as a gate interlayer dielectric film or a bitline interlayer dielectric film in a DRAM, shall be described as an example. In the related art, although BPSG has been used for a gate interlayer dielectric film in a DRAM, with the groove being embedded by causing the BPSG to reflow by a heat treatment at 750° C. or more, it has become necessary to suppress the heat treatment to 700° C. or less with the demands to carry out the process at a lower temperature. Accordingly, the use of a polysilazane SOG film having a high initial embedding property (an embedding property immediately after coating) has been tried. However, for the related art method, although the film does contract if the SOG film is subjected to a temperature of 450° C. or more, the film embedded inside the groove cannot contract, so that the resulting film has an increased wet etching rate. Specifically, an SOG film formation process which applies a thermal load of 450° C. or more to 700° C. is necessary. Thus, utilizing a method for producing a semiconductor device of an exemplary embodiment is effective.

Thus, according to an exemplary embodiment, the problem of a part of the SOG film embedded in a groove turning into a low-density film, thereby increasing the wet etching rate, can be avoided. As a result, it is now possible to obtain an intended shape, which has the effect of improving the yield of a device.

Further, since an exemplary embodiment is a method which controls the contraction ratio of an embedded film itself, unlike methods which alleviate stress by oxidizing a part of a silicon substrate or a silicon film, the effects of the pattern on the substrate or the width of the space can be suppressed to a minimum.

In addition, since an exemplary embodiment is capable of controlling the volume change and stress of a film by the composition ratio of the coating composition for forming an oxide film, a polysilazane and a hydrogenated silsesquioxane having a different polymerization degree can be widely adjusted. Further, the problems of polycrystalline silicon formation and of the resultant leak current between isolated devices, which occur when forming an oxide film only with polysilane, do not occur.

### EXAMPLES

### Example 1

In Example 1, a device isolation region (STI) was formed on a semiconductor substrate using a coating composition for forming an oxide film which was a mixture of a polysilazane and a polysilane.

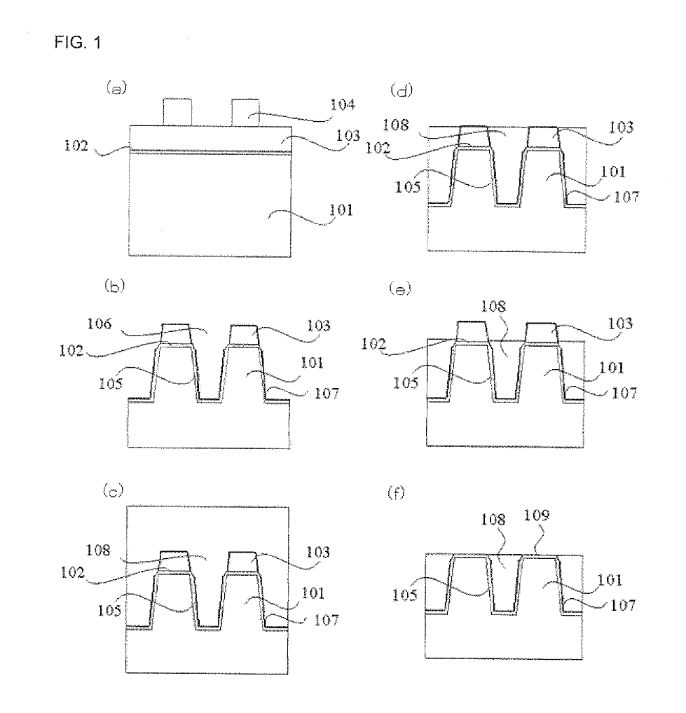

First, on a semiconductor substrate 101, a pad oxide film 102 (thickness: 9 nm) was formed by thermal oxidation and a nitride film 103 (thickness: 120 nm) was formed by LP-CVD. A pattern of photoresist 104 was formed on the nitride film 103 using a known lithography technique (FIG. 1(a)).

Next, with the photoresist 104 as a mask, the nitride film 103 and the pad oxide film 102 were patterned using a known etching technique. Then, the photoresist 104 was removed by ashing or the like in an oxygen plasma atmosphere. Next, with the patterned nitride film 103 as a mask, the semiconductor substrate 101 was etched to form a trench 106 (depth: about 180 nm) for device isolation. At this stage, the nitride film 103 was etched so that the thickness decreased from the original 120 nm to 80 nm. Further, to remove the layers damaged by the etching, a thermal oxide film 105 having a thickness of about 10 nm was formed on the inner walls of the trench. Then, to prevent the semiconductor substrate 101 from oxidizing by the heat treatment carried out later, a nitride film 107 having a thickness of 5 nm was formed by LP-CVD (FIG. 1(b)).

Next, the coating composition for forming an oxide film, which was a mixture of a polysilazane and a polysilane, was coated on the nitride film 107 by spin-coating to form a coated film. Here, used as the coating composition for forming an oxide film was a mixed solution prepared in an inert atmosphere of Spinfil 45002 (trade name; a mixture of 21 wt % of a polyperhydrosilazane and 79 wt % of dibutyl ether, manufactured by AZ Electronic Materials) and of cyclopentasilane in the same amount as that of the polyperhydrosilazane.

After the above-mentioned coating had been carried out at 25° C., UV light was irradiated for 1 minute in an inert atmosphere from a distance of 40 cm using a 200 W high-pressure mercury lamp. Then, baking was carried out in an inert atmosphere at 300° C. to volatize the unreacted cyclopentasilane and the solvent. A thermal oxidation treatment was further carried out for 20 minutes at 400° C. in an ordinary-pressure water vapor atmosphere and then the thermal oxidation treatment was continued for a further 20 minutes at 700° C. in a water vapor atmosphere. Next, the atmosphere was changed to a nitrogen atmosphere and the temperature was increased to 900° C. An annealing treatment was carried out for 10 minutes while maintaining the temperature. The temperature was lowered to 700° C., and the coated film was removed from the furnace. The coated oxide film 108 was thus formed using the coating composition for forming an oxide film which was a mixture of a polysilazane and a polysilane (FIG. 1(c)).

It is noted that when the coating composition for forming an oxide film was coated on a non-patterned silicon substrate, then irradiated with UV light and subjected to the heat treatment in the same manner as that mentioned above, the volume change from after the baking of the formed film to after the thermal oxidation treatment was +3%. Regarding the wet etching rate, the oxide film, which exhibited a volume change of +3% after being heat treated at 700° C. on the non-patterned silicon substrate, had an etching rate with hydrofluoric acid in a groove roughly equal to that of a part other than the groove, about 0.98 times, when the oxide film is formed on a silicon substrate formed with a groove pattern having a depth of 180 nm and a width of 60 nm. The change in curvature of a silicon substrate having a diameter of 300 mm was −70 μm with respect to the center of the silicon substrate.

Next, the nitride film 103 was ground as far as its upper edge as a stopper by CMP using a ceria slurry to planarize the surface (FIG. 1(d)).

Further, the upper edge of the coated oxide film 108 was lowered as far as the vicinity of the lower edge of the nitride film 103 by etching with hydrofluoric acid. At this stage, the upper edge of the coated oxide film 108 was set so as to come to about 20 to 40 nm above the upper edge of the semiconductor substrate 101 (FIG. 1(e)). Although it is ultimately desirable to align the upper edge of the coated oxide film 108 and the upper edge of the semiconductor substrate 101, a portion is left at this stage so that the coated oxide film 108 can be etched when the pad oxide film 102 is removed and the gate oxide film 109 is reset in a subsequent step.

Next, the nitride film 103 was selectively removed by etching with hot phosphoric acid heated to 150 to 160° C. Then, after conducting a necessary impurity ion implantation step, the pad oxide film 102 was removed with hydrofluoric acid. After washing, a gate oxide film 109 was formed by thermal oxidation (FIG. 1(f)).

According to the above-mentioned method, the upper face of the device forming region of the semiconductor substrate 101 could be aligned with the upper face of the device isolation region. It is noted that after forming the gate oxide film 109, a gate electrode is then formed thereon (not shown).

### Example 2

In Example 2, a gate interlayer dielectric film was formed using a coating composition for forming an oxide film which was a mixture of a polysilazane and a polysilane.

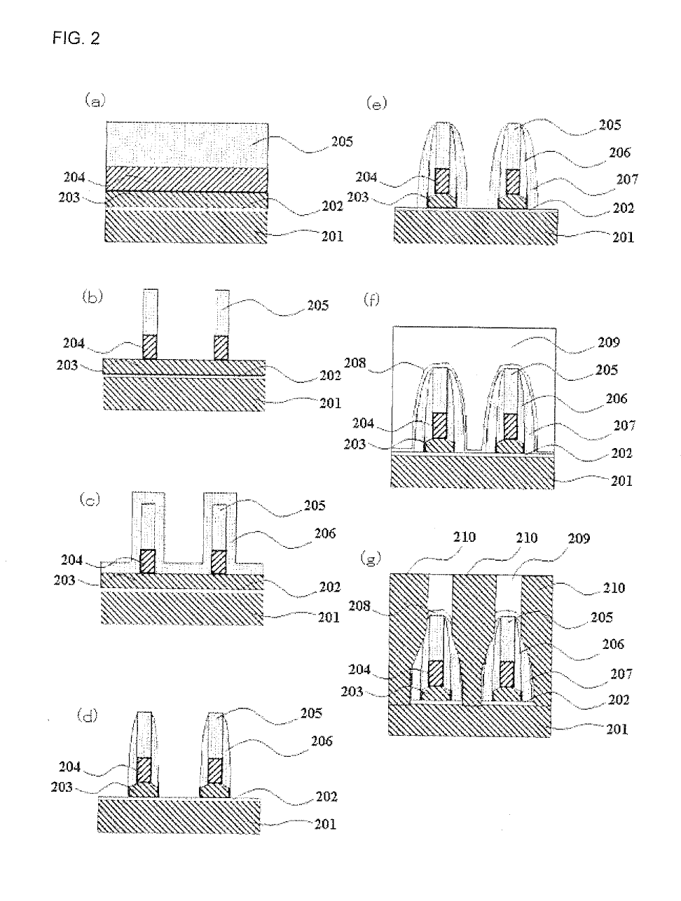

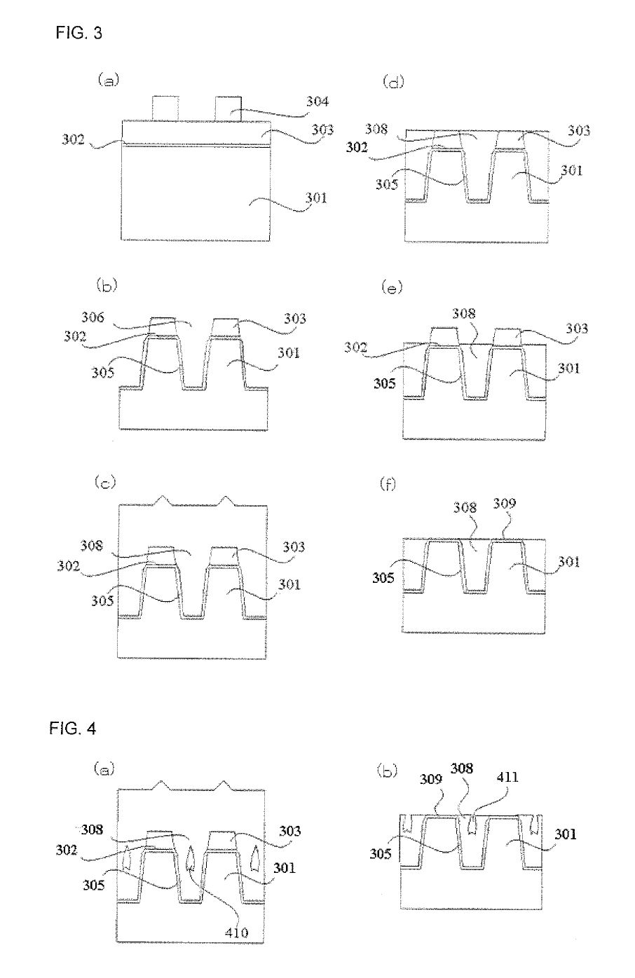

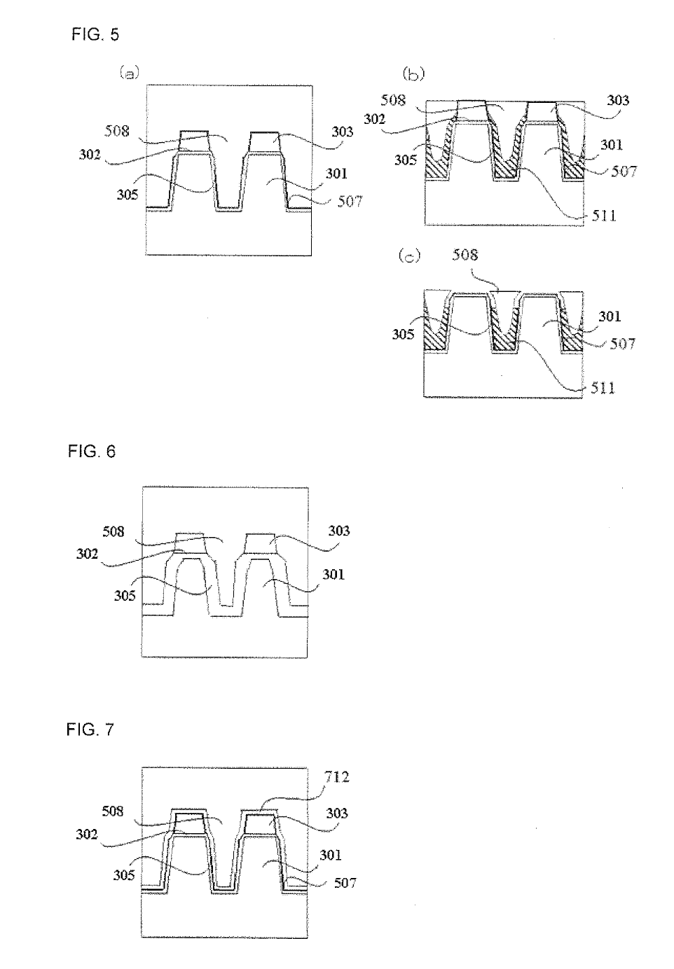

First, a gate interlayer dielectric film 202 was formed on a semiconductor substrate 201 having a formed device isolation region (not shown) such as STI. Next, a polysilicon 203 was formed on the gate interlayer dielectric film 202, and a metal electrode 204 of tungsten (W) or the like was formed on the polysilicon 203. It is noted that some works were carried out to suppress the interfacial resistance of a silicide and the like between the polysilicon 203 and the metal electrode 204. Further, a CVD nitride film 205 was formed on the metal electrode 204 (FIG. 2(a)).

Next, the CVD nitride film 205 and the metal electrode 204 were patterned using a known lithography technique and an etching technique (FIG. 2(b)).

Next, a nitride film 206 for preventing metal scattering was formed over the whole surface (FIG. 2(c)). Etching was then carried out so that the nitride film 206 remained forming the sidewalls. With the CVD nitride film 205 and the nitride film 206 as a mask, the polysilicon 203 was then etched (FIG. 2(d)).

Next, a nitride film 207 was again formed over the whole surface, and etching was carried out so that the nitride film 207 remained forming the sidewalls (FIG. 2(e)). Then, a nitride film 208 was again formed over the whole surface to prevent the semiconductor substrate 201 from oxidizing.

Subsequently, the same coating composition for forming an oxide film as in Example 1 was coated by spin-coating onto the nitride film 208 to form a coated film. After the coating, UV light was irradiated in the same manner as in Example 1 to make the polymerization reaction proceed. The coated film was then baked at a temperature of 100 to 300° C. to volatilize the solvent. Then, a thermal oxidation treatment was carried out for 30 minutes at 400° C. in a water vapor atmosphere. The thermal oxidation treatment was then continued for a further 30 minutes at 700° C. in a water vapor atmosphere. The coated oxide film 209 was thus formed using a coating composition for forming an oxide film which was a mixture of a polysilazane and a polysilane (FIG. 2(f)).

It is noted that when the coating composition for forming an oxide film was coated on a non-patterned silicon substrate, then irradiated with UV light and subjected to the heat treatment in the same manner as that mentioned above, the volume change from after the baking of the formed film to after the thermal oxidation treatment was +3%. The oxide film, embedded in the space portion between the gates formed thereby, and the non-space portion (upper part of the gate electrodes) had roughly the same etching rate with hydrofluoric acid. The change in curvature of a silicon substrate having a diameter of 300 mm was −30 μm with respect to the center of the silicon substrate.

Next, a contact hole was opened at a desired location, and a polysilicon plug 210 was formed (FIG. 2 (g)).

### Example 3

In Example 3, a device isolation region (STI) was formed on a semiconductor substrate using a coating composition for forming an oxide film which was a mixture of a hydrogenated silsesquioxane and a polysilane. Here, the method was carried out in the same manner as in Example 1, except that a solution prepared by mixing Type-12 (trade name; a hydrogenated silsesquioxane manufactured by Tokyo Ohka Kogyo Co., Ltd.) with cyclopentasilane in the same amount was used as the coating composition for forming an oxide film.

When this coating composition for forming an oxide film was coated on a non-patterned silicon substrate, then irradiated with UV light and subjected to a heat treatment, the volume change from after the baking of the formed film to after the thermal oxidation treatment was −3%. The oxide film embedded in the space portion between the gates formed thereby had an etching rate with hydrofluoric acid of roughly 1.1 times of the non-space portion (upper part of the gate electrodes). The change in curvature of a silicon substrate having a diameter of 300 mm was +60 μm with respect to the center of the silicon substrate.

The invention is not limited to the Examples.

This application is based upon and claims the benefit of priority from Japanese patent application No. 2007-151767, filed on Jun. 7, 2007, the disclosure of which is incorporated herein in its entirety by reference.

What is claimed is:

1. A method for producing a semiconductor device having a portion in which a groove is embedded with an oxide film, comprising:
coating the coating composition for forming an oxide film comprising:
a polysilazane or a hydrogenated silsesquioxane; and
a polysilane
on a substrate having the groove; and
forming the oxide film inside the groove by heat treatment in an oxidizing atmosphere.

2. The method for producing a semiconductor device according to claim 1, wherein the heat treatment in the oxidizing atmosphere is carried out at two temperature stages, and a temperature of a first heat treatment at the former stage is lower than a temperature of a second heat treatment at the latter stage.

3. The method for producing a semiconductor device according to claim 2, wherein the first heat treatment is carried out at 300 to 450° C. in a water vapor atmosphere, and the second heat treatment is carried out at 500 to 700° C. in a water vapor atmosphere.

4. The method for producing a semiconductor device according to claim 1, further comprising irradiating a light on the coating composition for forming an oxide film.

5. The method for producing a semiconductor device according to claim 1, wherein a device isolation region is formed by the oxide film.

6. The method for producing a semiconductor device according to claim 1, wherein a wiring interlayer dielectric film is formed by the oxide film.
